(19) United States
(12) Patent Application Publication
(10) Pub. No.: US 2010/0193017 A1
(43) Pub. Date: Aug. 5, 2010

(54) SOLAR PHOTOVOLTAIC STRUCTURE COMPRISING QUANTIZED INTERACTION SENSITIVE NANOCELLS

(76) Inventor: Gerald C. Huth, Ojai, CA (US)

Correspondence Address: THE NATH LAW GROUP, 112 South West Street, Alexandria, VA, 22314, US

(21) Appl. No.: 12/452,585

(22) PCT Filed: Jul. 10, 2008
(86) PCT No.: PCT/US08/08450

§ 371 Date: Mar. 26, 2010

Related U.S. Application Data
(60) Provisional application No. 60/929,781, filed on Jul. 12, 2007.

(51) Int. Cl. H01L 31/0352; H01L 31/00; H01L 31/18

(52) U.S. Cl. 136/255; 136/261; 136/256; 257/21; 438/73; 257/E31.033

(57) ABSTRACT

A light-to-electrical energy conversion device comprising a nano structure is formed on a surface of a semiconductor substrate. The nanostructure comprises an array of basic light antenna nanocells, with the individual antenna nanocells formed as “rectenna” structures. Light energy is absorbed within each independent antenna nanocell and converted to direct current. In one particular configuration, the structure of each basic nanocell comprises a cavity or cavities dimensioned to accept light as the wave of classical physics. These cavities function as quantum confinement sites for electrons that constitute an absorbing mass. The cavity dimensionality provides a determinative factor in wavelength discrimination of the nanocell structure.

### FIELD OF THE INVENTION

This invention relates to devices for converting light power to electric power and electric power to light power. More particularly it relates to achieving high light conversion efficiency in solar photovoltaic devices, comprising an array of independent, uniquely defined, light detecting and rectifying nanocells.

### BACKGROUND OF THE INVENTION

The photovoltaic solar cell was first developed over fifty years ago and used a pn junction diffused into silicon. In the intervening years, and after intensive research conducted around the world, the efficiency of such devices to convert light into electrical power has been only incrementally improved from that time. Efficiency values today are generally about 20-25% for highly optimized cells for space application and about 10% for commercially available terrestrial cells. Increasing the efficiency values of photovoltaic cells with resultant economic implications may be the single most critical energy research objective at this time in our history.

In contrast, it is now suggested that the light conversion efficiencies of the retina of the human eye and of the photoreceptors of photosynthetic plants and algae is very nearly 100%. It has been known for many years that the eye has actually evolved to the point of being capable of detecting light at the quantum limit, i.e., the retina can detect and “count” single (or at most a few) photons of light. Moreover, the eye accomplishes the feat of counting single photons at body temperature! This level of sensitivity has not been matched photonic device technology that is only able to single photons by applying use of cryogenic cooling to liquid helium temperatures or using high levels of electronic amplification (“photomultiplier tubes”), neither of which is available to photosensitive biological structures.

Alvin Marks proposes a strikingly revolutionary configuration for optical antenna structures in U.S. Pat. No. 4,445,050. U.S. Pat. No. 4,445,050 proposed using optical antenna structures as devices for converting “light power to electric power”. The embodiment put forward in that document used “antenna dipoles”. U.S. Pat. No. 4,445,050 treated the absorption of electromagnetic radiation in antenna engineering terms with the absorbed light energy was conducted to remote “rectification sites”. There was no description or understanding of the actual dynamics involved in U.S. Pat. No. 4,445,050, because that patent does not describe the actual mechanism of light interaction

These antenna design considerations of U.S. Pat. No. 4,445,050 were moot in with respect to separating the antenna a distance from the charge separating rectification function. The separation of the antenna a distance from the charge separating rectification function violates the fundamental principle for light interaction with an absorbing mass taught by Huth in U.S. Pat. No. 5,689,603 that light must be absorbed in an antenna space as the wave of classical physics but with this classical space being located immediately adjacent to a quantum confined electron space that constitutes the absorbing mass. U.S. Pat. No. 4,445,050 cannot achieve the fundamental requirement that absorbed light energy be transduced and purposefully utilized in the absorbing mass.

U.S. Pat. No. 5,689,603, to Huth describe various optically interactive nanostructures, and recognized that light must be directed to interact with quantum confined electrons to effect the most fundamentally defined process of the interaction of optical radiation with matter—the coalescence of a photon with an electron in an interaction in space (it will be recognized, and is a part of U.S. Pat. No. 5,689,603, that the converse of this—an electron-to-photon interaction resulting in light emission is also true). The rule governing this interaction is that light interacts as the wave of classical physics in cavities whose dimensions control wavelength, with these cavities necessarily being immediately adjacent to an electrical quantum confinement (EQC) region of fixed dimensions. A basic optically interactive nanostructure was described as constructed through choice of physical dimensions and materials used to fabricate it can be designed to encode for specific optical wavelengths (colors). In the nanostructure of U.S. Pat. No. 5,689,603 light is considered to be directed using sub-optical wavelength wave optics principles to specific sites in immediately adjacent structural matter that contain quantum confined electrons to complete the detection process. The exact design rules for fabricating this basic building block structure form the basis for U.S. Pat. No. 5,689,603. U.S. Pat. No. 5,689,603, however, further teaches that it is possible to array these wavelength tunable basic structures over extended two dimensional surfaces to produce an optically interactive surface that can be designed to match any incident optical spectral shape that it is desired to detect (or again, conversely, emit).

Since the nanocell set forth in this disclosure involves both the wave nature of incident light and with the absorbing mass viewed from a quantum standpoint, it useful to define the light interaction mechanism as being generally “quantized” rather than using the pure quantum construction that “a photon interacts”. Because of the common usage of terminology to photon interaction this description uses the term “photon” interchangeably with the quantized terminology.

U.S. Pat. No. 5,689,603 is incorporated herein by reference for all purposes, including for describing embodiments and characteristics of the present invention.

### SUMMARY OF THE INVENTION

The present invention provides a nanocell, and structures comprising an array of nanocells, that provide a high light to electrical power efficiency. For the purposes of this invention, a “nanocell” is defined as an energy converting structure comprising (1) individual sub-micron dimensioned (“antenna”) light interaction space or spaces being necessarily immediately adjacent to a quantum confined electron (“EQC”) space or spaces that form the absorbing mass (2) wherein contained within each nanocell a structure that provides a function to separate electrical charge (such as, for example, a pn or Schottky barrier junction) with this complete photovoltaic nanocell being termed a “rectenna” Further, these nanocell sites, in classical terminology act as “optical antennas”, and therefore may be purposefully “tuned” to any light wavelength from the visible to the near infrared by altering light absorbing cavity dimensions With dimensions of the EQC sites remaining constant. The array of nanocells of the present invention is provided wherein a common electrical connection is applied to each end of each nanocell, wherein the ends are the charge-separated ends of the nanocell, and wherein the electrical connections form a circuit to carry direct current generated at each nanocell.

An array of the above described nanocells uniquely provides a solar photovoltaic device structure capable of detecting individual photons (or light quanta) and converting these single-photon signals into electrical energy. As noted above, because separation of electrical charge is maintained within each nanocell, many millions of individual “rectenna” sites may be obtained over a square inch of area of the surface of the device. Simple calculation shows that even at solar fluence the probability of two photons being incident on a single optical antenna site of this large number of individual cells is negligible. The nanostructure thus precludes out-of-phase signal cancellation and increases efficiency beyond the confines of expected classical solar cell models.

It is shown in the present invention that each nanocell provides a site capable of detecting and converting single-photons into electrical energy. It follows from a simple calculation showing that even at solar fluence (˜10>21 photon/m2/sec) the probability of two photons being incident on a single light interacting antenna nanocell of this large number (density ˜10>14 nanocells/m2) of individual cells is negligible. The combination of solar fluence, the density of nanocells and the wavelength of light determine that ˜10>7 discrete light cycles will be incident on each nanocell at normal solar fluence. This is sufficient to activate each nanocell rectenna site and preclude out-of-phase signal cancellation an effect that will dramatically increase solar cell efficiency. Existing solar cell technology relies upon devices designed to convert light to electrical power by absorbing light and separating charge in the “vertical” dimension through the silicon layer. In the present invention, light to electrical power conversion also utilizes the “lateral” organization of an array of nanocells. In the most elemental embodiment of the present invention, nanocells of the present invention absorb light at the spaces immediately adjacent to the quantum confined electron space, and the light energy is then transferred laterally into the neighboring quantum confined electron space wherein the energy is absorbed and charge separation occurs. Extended arrays of nanocells can be purposefully configured to define sensitivity to the polarization of incident light or, using extended arrays of varying wavelength response to detect entire light spectra. The latter might be used, for example, to detect with high efficiency chromatically aberrated light from a condensing lens.

The nanocell structure of the present invention is formed as a light-to-electrical energy conversion device, on the surface of a silicon or other semiconductor or insulating substrate. In the present invention, the nanostructure establishes an array of nanocells sensitive to optical wavelengths, and each of the nanocells includes an energy conversion function to convert optical energy formed within each nanocell to direct current

Each nanocell functions as an individual light detection site, each containing a charge rectifying structure such as, for example, a pn junction or Schottky barrier, thus forming a “rectenna” of sub-micron dimensions The array is formed as a surface nanostructure comprising a multiplicity of nanocells, such that dimensional modifications of the surface nanostructure result in control of optical response. The light detecting cavity achieves a reception of a light wavelength detected as a function of the dimensionality of the cavity or grouping of cavities, and as a function of the orientation relative to the polarity of the incoming light wave. In the most elemental embodiment of the present invention, the nanocell has at least one light detecting cavity adjacent to an EQC site. In other embodiments of the present invention, nanocells may be grouped to have more than one light detecting cavity, for example, 2, 3, 4, 5, 6, 7, 8, around a central EQC site. Thus a light detecting array may contain designed groupings of nanocells configured to detect different wavelengths or polarization angles of light. It mat be desired, for example, to laterally detect an entire spectrum of light from short to long wavelength limit. This capability follows from each nanocell or groupings of nanocells to being dimensionally designed to detect specific light wavelengths.

As noted above, each light-to-electrical energy conversion antenna nanocell absorbs light as a classical physics waveform. Dimensions of the optical cavity of the nanocell determine wavelengths of absorption. It will be appreciated that the basis for antenna behavior of the present invention, follows from lateral dimensions of the cavities of the order of lambda/2n where lambda is the wavelength of light and n is the refractive index of the absorbing medium. This results in antenna nanocells that are of sub-micron (<10>−6 m) dimensions. The cross-sectional geometry of each of the cavities of a nanocell, parallel to the planar surface of the array of a nanocells, may be the same or different, and may be regular or irregular. In one embodiment of the present invention, the cross-sectional geometry of a cavity comprises at least one concave inner surface and/or at least one linear side, for example, circular, semicircular, elliptical, semi-elliptical, any geometric shape having at least one concave side, triangular, rectangular, hexagonal, any geometric shape having at least one linear side, or a shape having at least one linear side and least one concave face. In each case, however, electron quantum confinement conditions must be maintained in nanocell receptor design.

As taught by Huth in U.S. Pat. No. 5,689,603 (A Fundamental Light Interactive Nanostructure) in addition to lateral dimensionality, cavity depth of nanocells must be considered in defining the wavelength absorbed. In visible light detection these depths range from 5 to 50 microns into the silicon or other substrate. In another embodiment of the present invention, the conversion device may comprise a concentration of nanocells ranging from 700 to about 3000 nanocells in one mm² of device area. In another embodiment of the present invention, the conversion device comprises a concentration of nanocells selected from 100, 200, 300, 400, 500, 600, 700, 800, 900, 1000, 1100, 1200, 1300, 1400, 1500, 1600, 2000, 3000, 4000, or 5000 nanocells in one mm² of device area. In one embodiment of the present invention, the conversion device comprises a concentration of nanocells of about 1500 nanocells in one mm² of device area. 1500 individual nanocells per mm² equals 150,000 conversion sites per cm². In one embodiment of the present invention, an individual solar cell device may have a nanocell array area ranging from 1 mm² to 300 cm², with a possibility of scaling to a significantly greater area. In another embodiment of the present invention, a single nanocell may be used by itself as a lone solar cell device, for example, for nanostructure applications. In other embodiments of the present invention, groups of 2 to 100 nanocells may be used together as a solar cell device, for example, for size-restricted applications.

Each of the light detecting cavities of a single nanocell may have the same or different cross-sectional area along the depth of the cavity. In a particular configuration of the present invention, a wavelength broadening “Q” of each nanocell can be geometrically determined by a degree of taper of the EQC OR light-accepting cavity structure. The cavities and EQC centers of the present invention are configured to provide an intended optical response characteristic. In one embodiment of the present invention, the cavities and EQC centers are configured with at least one EQC center surrounded by a ring of wavelength tuned cavities for detection of a polarization characteristic of the absorbed light.

### BRIEF DESCRIPTIONS OF THE DRAWINGS

The features and nature of the present invention will become more apparent from the detailed description set forth below when taken in conjunction with the drawings and their reference characters identifying corresponding features throughout.

FIG. 1 is a diagram of a single optical nanocell composed of a variable dimensioned light accepting cavity and a fixed dimensioned quantum confined electron space. A configured array of these nanocells comprises the overall high efficiency solar cell structure that is the fundamental embodiment of the present invention.

FIG. 2 is a diagram an array of nanocells forming a solar light conversion structure of one embodiment of the present invention. A combination of the lateral and vertical dimensionality of the nanocell determines the wavelength absorbed according to the classical/quantum mechanism as described herein for some embodiments of the present invention. A top layer or grid work of optically transparent electrically conductive material, such as indium tin oxide, completes the electrical power generating circuitry for this particular embodiment of the present invention.

FIGS. 3A and 3B show an array of laterally ordered (or designed) nanocells that can be used to meet specific wavelength or spectral detection requirements This figure depicts an important aspect underlying such design wherein the spatially ordered character of electron quantum confinement EQC centers (the white areas) and the entrance of geometry in controlling light detection efficiency. The generally random statistical distribution array of EQC centers in 3A corresponds to low detection efficiency values. This type of random distribution array is characteristic of nanostructure surfaces such as “porous silicon” fabricated by electro-etching of silicon surfaces. The statistically distributed light absorbing cavities characteristic of contemporary porous silicon surfaces do not meet the spatial ordering (of nanocells) requirements necessary to achieve high light detection efficiency. Additional modification of normal porous silicon, for example, through use of nanolithographic methods would be needed to create the wavelength customized cavities and/or the nanocell boundaries of the present invention, not to mention adding the nanocell-isolated PN junctions for deriving electrical power from the nanocell arrays. Such lateral spatially ordering of the nanocells of an array will result in high detection efficiency such as shown in FIG. 3B.

FIGS. 4A, 4B, and 4C, depict examples of how the variation of the spatial array of nanocells can be used to achieve different optical detection properties according to the present invention. In 4A. In one embodiment of the present invention, tunable light-accepting cavities can be arranged around a central EQC site (or “pillar”, or “antenna”) in a “rosette” arrangement to form a grouping of nanocells that will accept various angles of light polarization. Such a grouping is seen, for example, at 7-8 degrees of retinal angle in the retina of the eye that is known to be insensitive to light polarization

4B. Shows a spatially ordered array of nanocells centered around EQC spaces that could be fabricated in one embodiment of the present invention, for example, by using nanolithographic technology. The EQC regions in this embodiment are defined by the dimensionality of the 2-D silicon “web” existing between light-accepting cavities in place of the quantum “wires” in the above diagram. Again, the wavelength sensitivity of this structure can be changed by altering dimensions of these light-accepting cavities.

4C. It will be appreciated that, using the fabrication methods of 4B, a linear light-accepting cavity/EQC adjacent, structure can be formed to accept light of only a single polarization angle.

### DETAILED DESCRIPTION

The present invention relates to a novel light to electrical power converting structure comprised of individual “nanocells”, each being defined as an energy converting structure comprising (1) A sub-micron dimensioned, “antenna” light interaction space or spaces wherein light is absorbed as the wave of classical physics, with this space or spaces being immediately adjacent to a fixed dimension quantum confined electron space or spaces (“EQC”) that forms the absorbing mass, and, (2) wherein each nanocell provides for separation of electrical charge (using, for example, a pn or Schottky barrier junction) contained within each nanocell. The single or fundamental nanocell can also be described as the basic “building block” of an overall solar cell array structure. In some embodiments of the present invention, each nanocell comprises a optical light wave-accepting region fabricated, for example, as a cavity on the surface of a semiconductor, which is intimately and directly bounded by surrounding receptor regions, which are either of a discrete shaped free standing “pillars” or dendrites, or alternatively formed as thin “webs” separating adjacent cavities but are generally of sufficiently narrow dimension to act as a quantum confinement region for electrons in the specific material used. This quantum confinement region is a readily calculable dimension for semiconductor materials. The light wave-accepting region of the basic nanocell performs the function of an optical waveguide for visible light and, crucially, is of dimensionality smaller than the wavelength of light. It is believed that light is surprisingly conducted outside of (rather than internally) such sub-micron dimensioned fiberoptic waveguides. Further, it has been proposed that this light energy is transduced laterally from such waveguides using evanescent wave phenomena into absorbing media. This mechanism would seem to underlie the basic tenet of this invention that light energy is transduced laterally into necessarily immediately adjacent EQC regions that constitute the absorbing mass.

With the dimension of the electron quantum confinement region fixed by the material chosen, the dimensions of the cavity light absorbing are chosen to absorb light of a desired wavelength or band of wavelengths. The light wave-accepting region then directs light into specific regions of space within the optical nanocell where they will coalesce with quantum confined electrons in the receptor portion of the structure. Thus, the basic light-accepting nanocell can be precisely dimensioned to absorb a particularly chosen narrow or defined band of radiation. The basic wavelength tunable building block structure can then be replicated or arrayed laterally to form large scale optical devices formed from these nanostructure elements. The basic nanocell may be arrayed over a surface as shown schematically with the wavelength response and thus geometry of each device being independently specified. The basic nanostructures could be configured to respond, for example, to a selected set of colors (the “primary” colors for example,) and such elements could be arrayed to provide nanoscale optical display devices.

Geometrical considerations of the basic nanocell can also be used to achieve “broad banding” of light response around a central wavelength detected. Circular and non-circular shapes can be used to achieve different effects. In each case, however, electron quantum confinement conditions must be maintained in receptor design. The optical separation distance can be varied while maintaining the central electron quantum confinement dimension of the receptor.

The dimensional parameters of the nanostructure are described in U.S. Pat. No. 5,689,603. These include the center-to-center distance between adjacent electron quantum confinement regions, the radius of a single electron quantum confinement region, the diameter of the optical light wave-accepting region, the maximum depth of the optical light wave-accepting region corresponding to the wavelength-specific design point for the nanostructure, and the depth calculated using the same equations for other shorter wavelengths that can be extracted at shallower depths of the region. These represent the depths at which photons of the designed wavelength coalesce with quantum confined electrons in the most fundamental definition of optical detection. The parameters control the optical refractive indices of the substrate material used to form the nanostructure.

Light incident upon such a nanostructure enters the light absorbing region and travels a distance down the length of the region before coalescing with a quantum confined electron in an adjacent quantum confinement region. Determination of the coupling coefficient between neighboring quantum confinement regions is based on an analysis of radiation power transfer between optical fibers by McIntyre and Snyder, Journal of the Optical Soc. of America, Vol. 63, No. 12, 1973. The quantum confinement region and the coupling coefficient is related to the geometry of the basic optical nanocell.

Calculations of these parameters can be performed according to U.S. Pat. No. 5,689,603. For a given nanocell geometry, a spectrum of wavelengths absorbed into the light absorbing cavity are each absorbed at a different point along the vertical height of the region. A shorter wavelength corresponding to higher frequency, e.g., blue light, is absorbed at deeper depths, while longer a wavelength travels less deeply into the light absorbing space and thus interacts with quantum confined electrons at shallower depths along the receptor. Therefore, by selecting an optical wavelength, .lambda, for which it is desired to tune the nanostructure to, and by fixing r to calculable, quantum confined electron dimensions for the substrate material chosen (roughly 10 nanometers for silicon) it is possible using the above relationships to calculate the width and height for the light absorbing cavity region.

Random and periodic nanocell structures can be conveniently formed from silicon using a variety of techniques known in the art, including, but not limited to, the following: reactive ion etching; lithography techniques; wet-chemical etching; and laser interference techniques. In one example, nanocell-sized structures are first formed in photoresist followed by pattern transfer to silicon using an appropriate combination of wet and dry etching techniques. Silicon reactive ion etching (RIE) techniques are well characterized, and wet-chemical etching of Si is also well understood. Further, combination of techniques to form deeply etched nanocell structures based multiple etch and deposition cycles may be used to create arrays of nanocells.

The surprising discovery of “porous silicon” (or “PS”) in 1991 by Canham created a unique and serendipitous way of forming arrays of the basic nanocells of this invention. PS is a nanostructure formed by electro-etching of silicon in mixtures of hydrofluoric acid. Characterized by very deep “pores” and intervening silicon “pillars” (or webbing) The aspect ratio (depth-to-surface feature width of the structure) takes values of 20-30:1 Similar aspect ratio of the light detecting outer segments of the retina of the human eye takes even more amazing values of ˜50:1.

The disadvantage of PS surfaces as currently etched is a characteristic low light conversion efficiency (only a few percent). In the spirit of this invention this derives from geometrical considerations resulting from the chaotic, statistical distribution of pores and pillars in the silicon PS nanostructure. The nanocells of this invention therefore reflect this chaotic distribution with resultant low conversion efficiencies. There are, however, a number of methods for providing a spatially ordered array of the basic light-accepting nanocells of this invention using the PS electro-etching method in combination with known light interactive effects and/or using nanolithographic semiconductor fabrication methods.

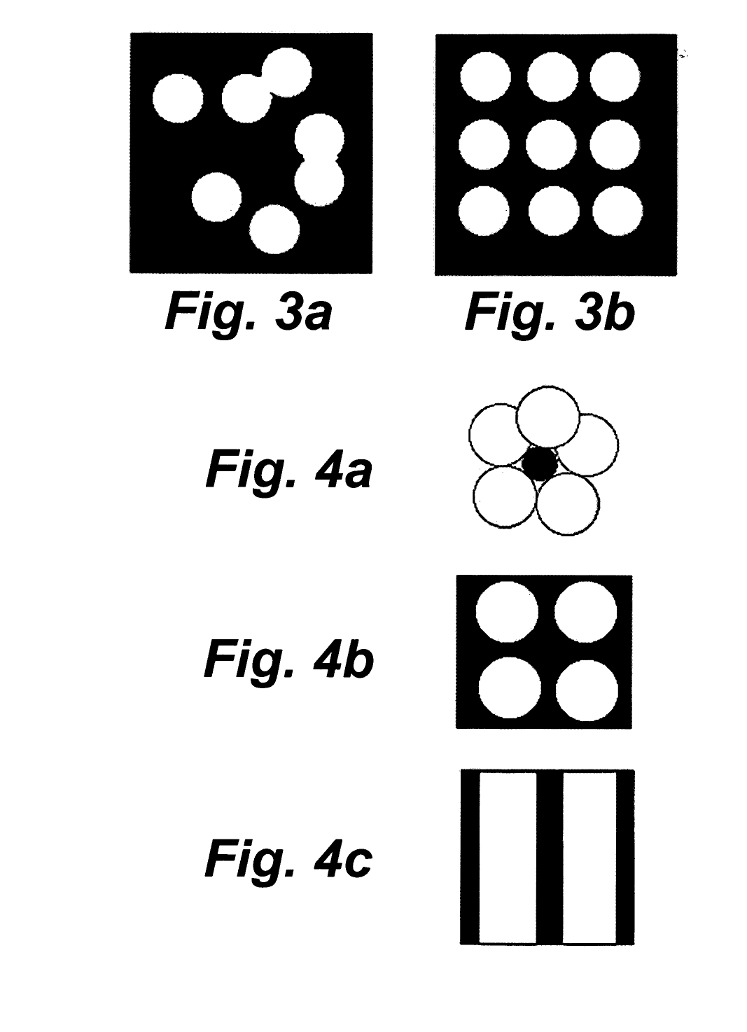

One light-interactive effect that can be applied follows from the work of Dworschak et al (1) and Young et al (2) who studied the interaction of pulsed laser radiation with semiconductor surfaces at two wavelengths. In this series of experiments, laser pulses were made incident onto silicon and germanium surfaces with laser intensity controlled so as to cause only partial melting of the surface. The surface was then chilled quickly so as to preserve any structure produced. The result was a periodic “grating” whose period matched the wavelength of the orthogonally incident light energy. When the 1.06 micron wavelength of the neodymium laser was used the grating produced displayed exactly this period. The 10.6 micron wavelength of the CO2 laser produced a period corresponding to this wavelength (shown from Dworschak to the left in FIG. 3). The Young paper goes on to study structures produced by different laser fluences and to discuss possible mechanisms involved but the central finding seems to be the one I have noted, i.e., that the wavelength of incident light is reflected laterally onto a surface . . . which fundamentally supports the geometrical concept. Another result of the same nature again using the 10.6 micron radiation of the CO2 laser—and copper surfaces—was produced by Siegrist et al (3). Again one sees that the periodicity of the surface structure is related to the orthogonally incident light wavelength with their result shown in the right hand view of FIG. 3.
1. K. Dworschak, J. E. Sipe, H. M. van Driel, “Transitions Between Ordered and Disordered Solid-Melt Patterns Formed on Silicon by Continuous Laser Beams: Competition Between Electrodynamics and Thermodynamics”, Ref. unknown.
2. Jeff F. Young, J. E. Sipe, and H. M. van Driel, “Laser Induced Periodic Surface Structure. III Fluence Regimes, the role of feedback and details of the induced topography in germanium”, Physical Review B, Vol. 30, No. 4, 15 Aug. 1984
3. Siegrist, M., Kaech, G., Kneubuhl, F. F., “Formation of Periodic Wave Structures on the Dry Surfaces of a Solid by TEA-CO2 Laser Pulses”, App. Phys, Vol. 2, p. 45, 1973

This method, the purposeful incidence of specific light wavelength incident on the silicon surface during the electro-etching step can result in A PS nanostructure that takes on the wavelength emitting-absorbing character of the incident wavelength.

Alternatively, nanoliographic methods such as Focused Ion Beam (FIB) Technology may be used in conjunction with the PS electro-etching methods or independently to fabricate nanocell array configurations. In the former, a raster scanned FIB can be used to write an ordered array of surface damage sites that will become during the PS electro-etching process the sites of pore nucleation. The geometrically increased light conversion efficiency that is the teaching of this invention will result. It will be obvious that nanolithographic methods may also be used independently to form light detection structures with desired characteristics.

It is expected that silicon will be used initially as the material of choice for forming these nanostructures because it exhibits excellent mechanical strength and thermal properties that are consistent with the requirements of forming relatively high aspect ratios to achieve the optical effects that are the basis for this invention. And too, current high resolution nanolithography has fundamentally been developed around this material. It will be understood by those skilled in the art that nanolithographic technology comprises such as either x-ray mask patterning or electron or ion beam pattern writing techniques to define the optical nanocell and its deployment over extended area this being followed by appropriate etching techniques to etch and define the specified light absorbing region. Other semiconductor, dielectric, or conducting materials may also be employed to fabricate the optical nanocell of the invention using nanolithographic techniques as will be appreciated by those skilled in the art.

Configurations of the Basic Complete Rectenna Nanocell

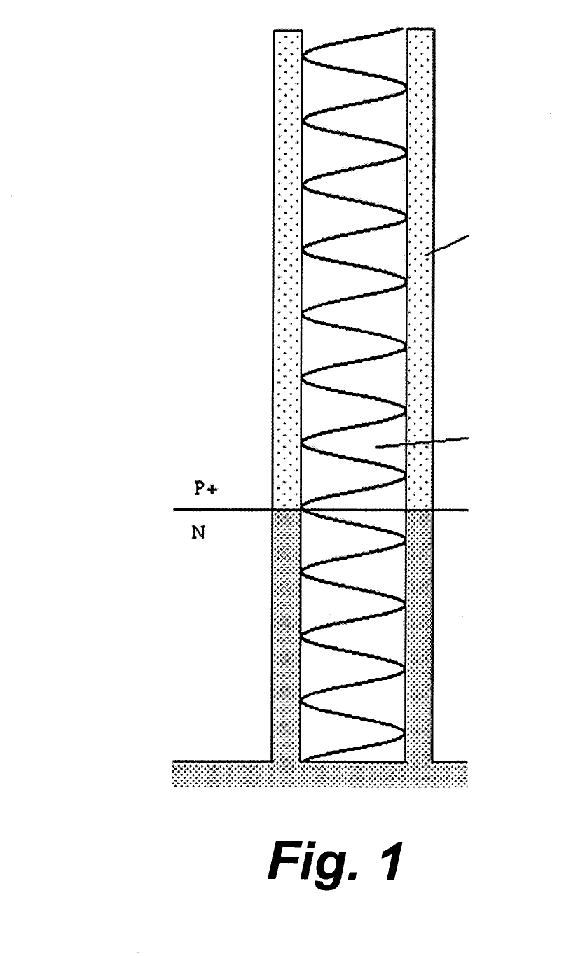

FIG. 1 is a diagram of a basic nanocell. The nanocell is formed of a cavity with sidewalls. The sidewalls form an immediately adjacent electron quantum confinement region or wave-accepting region. Wavelength discrimination of the wave-accepting region is determined by a combination of lateral and vertical dimensions of the cavity. The electron confinement region is of fixed dimension determined by the dielectric properties of the substrate. A pn junction is formed in the electron confinement region. The pn junction may be at an arbitrary depth, or at a depth determined in accordance with a desired response of the optical nanocell. The depth of the pn junction would be selected to isolate each nanocell from the underlying structure. While a particular configuration of p over n is depicted, the actual configuration would be one of design choice and could, for example, be inverted as n over p.

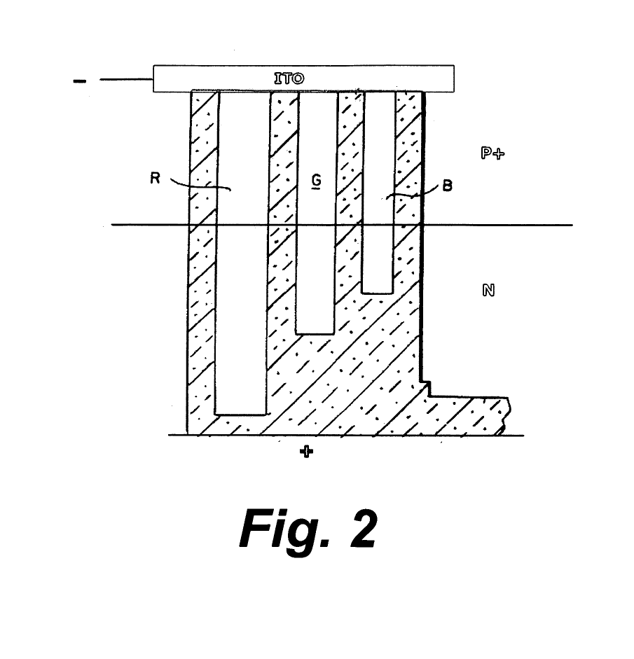

FIG. 2 is a diagram showing a wafer with a top plate forming conductive structure connecting to the upper junction region. The top plate must admit light, either through transparency or because it is made porous to coincide with the porosity of the underlying silicon. An example of a suitable transparent material for the top plate is indium tin oxide (ITO). The top layer can be formed after the formation of the underlying nanostructure. In nanolithographic formation processes the top layer may be used as a mask to control the etching of the underlying silicon. Alternative connection strategies are also possible.

This view of the cross section of a solar photovoltaic device depicts pores of different depth and volume forming individual antenna nanocells in, in this case, porous silicon. One method for quantifying the necessary volume of cavities for the desired wavelength to be absorbed is known in the art and is found in U.S. Pat. No. 5,689,603, to Huth, and is incorporated herein by reference in its entirety for all purposes. A conductive top plate forms a conductive structure connecting to the upper junction region. The top plate must admit light, either through transparency or because it is made porous to coincide with the porosity of the underlying silicon. An example of a suitable transparent material for the top plate is indium tin oxide (ITO). The top layer can be formed after the formation of the underlying nanostructure, or can be formed beforehand. It is also possible to use the top layer as a mask to control the etching of the underlying silicon. The central horizontal line defines a barrier between the upper P+ region and the lower N region. An example of a suitable barrier is a P/N junction or Schottky barrier

It is noted that it is possible to construct the underlying silicon nanostructure in one geometric arrangement, while constructing the top plate in a different geometric arrangement, so long as optical characteristics of the top plate result in a nanostructure (including the top plate) which has the desired dimension. Thus, for example, it is possible to construct the silicon in the form of antenna structures, while establishing a porous grid using the top plate. The combination of the silicon structure and the top plate structure forms the complete nanostructure, which would include geometric elements of the top plate.

The depths of the nanostructures will be able to be uniform or varied, depending on the desired spectral response. In one embodiment of the present invention, a starting wafer is prepared, and optionally implanted with dopants. The starting wafer may be a p or n type starting wafer or may be doped in a deep drive implant. The result will be a subsurface layer of conductive material. Subsequent to the deep drive implant, a first junction implant is applied, to create a first semiconductor type for a pn junction. The first semiconductor may be integral with the deep drive implant or may be a separate implant step. This is followed by a second implant, to create a second semiconductor type for the pn junction. The pn junction may be a p-type material above n-type material, or as a pn junction with n-type material above p-type material. The wafer may be further implanted with impurities suitable for absorption of optional energy for the purpose of conversion of optical energy to electrical energy. While it is believed possible to generate a fairly regular pattern of porous silicon by controlling the parameters of the etch process, it may be desired to optionally create a damage or etched pattern on the wafer in order to further control the etch pattern. A patterned or non-patterned mask or shielding layer is applied or created on the wafer, and an etched pattern is created by exposure to energy, such as optical energy, ion beam energy or x-ray energy. The energy must be sufficient to either etch or otherwise affect the mask or the wafer. Alternatively, in one embodiment of the present invention, the etching may be accomplished on a silicon wafer by applying a strong acid, such as HF, wherein the wafer has been optionally doped to create an acid etch site, masked, shielded, or a combination thereof. In a particular embodiment of the present invention, a wafer of porous silicon may be further etched with a patterned or non-patterned mask or shielding layer applied or created on the wafer, and a further etched pattern is created by exposure to energy, such as optical energy, ion beam energy or x-ray energy, wherein the porous silicon already comprises the light absorbing cavities and the final masking and etching creates the lateral boundaries of each nanocell.

The pattern may be applied in a raster scan or any other convenient manner to create the desired pattern. The wafer may then be etched to form the physical dimensions of the nanostructure of porous silicon. The above description is given by way of an example only, in that there are a wide variety of way in which a deliberate pattern can be created on a semiconductor substrate. The scan can be either configured to directly ablate the wafer, or otherwise create a pattern for a preferential pattern for creating the porous silicon. The pattern may also be created on a sacrificial layer, such as a mask or other composition of material capable of being used to pattern the silicon. It is further possible to exact the pattern during the etch process itself, either with the use of energy or otherwise control the etching of the substrate to achieve the desired pattern.

It is noted that the particular pattern may not be essential, although providing a particular pattern is expected to increase the efficiency of the conversion of light to electrical energy.

FIGS. 3A and 3B are diagrams depicting arrangements of nanocells. An array of nanocells can be laterally ordered (or designed) to meet specific wavelength or spectral detection requirements of embodiments of the present invention. This figure depicts an important aspect underlying such design wherein the spatially ordered character of electron quantum confinement EQC centers (the white areas) controls light detection efficiency. The generally random statistical distribution array of EQC centers in 3A corresponds to low detection efficiency values. This type of random distribution array is characteristic of porous silicon fabricated by acid etching. Spatially ordering these centers laterally using, for example, microcircuitry fabrication technologies and/or ion beam technologies results in high detection efficiency such as shown in FIG. 3B.

FIGS. 4A, 4B, and 4C are diagrams depicting examples of how the variation of the spatial array of nanocells can be used to achieve different optical detection properties according to the present invention. As depicted in FIG. 4A, in one embodiment of the present invention, tunable light-accepting cavities can be arranged around a central EQC site (or “pillar”, or “antenna”) in a “rosette” arrangement to accept various angles of light polarization. In another embodiment of the present invention, this structure is fabricated using porous silicon etching of a masked silicon wafer surface, and/or in combination with ion-beam etching. It follows from the teaching of this invention that the lateral dimensions of the light-accepting cavities of the device of 4A determine the wavelength detected. In one embodiment of the present invention, millions of these rosette-shaped nanocells may be created over the surface of a solar converting structure.

FIG. 4B shows a spatially ordered array of EQC centers that could be fabricated in one embodiment of the present invention, for example, by using microcircuitry fabrication technology. The EQC regions in this embodiment are defined by the thin dimensions of the “web” between light-accepting cavities. Again, this structure can be wavelength tuned by altering dimensions of these cavities.

As can be seen in FIG. 4C, it will be appreciated that, using the fabrication methods of 4B, a linear cavity structure can be formed to accept light of only a single polarization angle.

A nanostructure dimensioned for quantum light interaction is provided in the present invention with a light conversion capability such that energy is transferred across the nanostructure for conversion between electrical energy and optical energy. In one configuration, light incident on the nanostructure interacts at the quantum level through the nanostructure, with the nanostructure forming individual antennas and optical energy conversion structures in the form of “rectennas”.

High Efficiency Solar Cell Development

A light interaction effect is able to be used in matching a photosensitive nanosurface to the solar spectrum.

The induction of light wavelength-associated periodic surface structures results in the wavelength of light incident onto a surface being reflected laterally onto that surface. This provides an alternative to the usual optical construction in which wavelength is represented by the dimension orthogonal to the surface.

A nanostructure consonant with the solar spectrum will result if an attenuated solar spectrum were made incident through a condensing lens onto the silicon surface during the photosensitive electro-etching process. This can be termed the “rainbow experiment”, and suggests that the resulting luminescence would be a replica of the human retina. This also provides a basis for a retinal prosthesis.

Contemporary solar cell theory uses the construction that wavelength sensitivity is a function of vertical depth into the solar cell structure (short wavelength blue light is absorbed near the surface of the cell, long wavelength red light deeper into the structure, etc.). The antenna approach requires that wavelength sensitivity resides in lateral aspects of cell design.

### CONCLUSION

Having described the invention in detail and by reference to the embodiments thereof, it will be apparent that modifications and variations are possible, including the addition of elements or the rearrangement or combination or one or more elements, without departing from the scope of the invention which is defined in the appended claims. Thus, the present invention is not intended to be limited to the embodiments shown herein but is to be accorded the widest scope consistent with the principles and novel features disclosed herein.

What is claimed is:

1. A light-to-electrical energy conversion device comprising a nanostructure formed on a surface of a silicon or other semiconductor substrate comprising an array of unique basic light antenna nanocells sensitive to optical wavelengths with each individual antenna nanocell containing a charge rectification function forming a “rectenna” structure to convert light energy absorbed within each independent antenna nanocell to direct current, and with each nanocell provided with a common electrical connection and a second electrical connection applied to the semiconductor or insulator substrate.

2. The light-to-electrical energy conversion device of claim 1, wherein the structure of each basic nanocell comprises a cavity or cavities dimensioned to accept light as the wave of classical physics immediately adjacent to a site or sites dimensioned as quantum confinement sites (“EQC”) for electrons that constitute the absorbing mass, wherein with cavity dimensionality provides a determinative factor in wavelength discrimination of the nanocell structure.

3. The light-to-electrical energy conversion device of claim 1, wherein individual antenna rectenna nanocells can be purposefully grouped or arrayed in lateral designs to effect a variety of light detection applications to include detection of entire spectra to including only single or a number of polarization angles.

4. The light-to-electrical energy conversion device of claim 1, wherein the sub-micron dimensions of the basic rectenna nanocell, and resulting high density of such nanocells per unit areas, provide a situation where light photons at full solar fluence can be activated individually by photon interactions precluding overlap of light interaction signals with resultant loss of light detection efficiency that forms the basis for the increased light conversion efficiency of the solar cell structures.

5. The light-to-electrical energy conversion device of claim 1, wherein a degree of spatial order achievable in a lateral design for an array of nanocells provides a determinative factor in detection efficiency.

6. The light-to-electrical energy conversion device of claim 1, wherein an array of sub-micron dimensioned antenna nanocells of the same RGB triad or ribbon macro-designs of light interactive phosphor displays that would provide color imaging.

7. The light-to-electrical energy conversion device of claim 1, wherein the nanocells transmit as well as absorb light energy, wherein arrays of nanocells provided with a function to inject electrons into the EQC regions to function as light emitting structures.

8. The nanocell of claim 7, wherein the light emitting surfaces have a configuration selected according to a desired spectral content or shape.

9. The light-to-electrical energy conversion device of claim 1, further comprising replication of the solar spectrum can by incidenting the solar spectrum (attenuated) through a condensing lens onto a silicon surface undergoing the PS electro-etching process, wherein a chromatic aberration of such a lens replicates onto the silicon surface in the form of an array of light detection efficiency nanocells.

10. The light-to-electrical energy conversion device of claim 9, wherein, the array replicates a response of the retina of the human eye to provide a retinal prostheses.

11. The light-to-electrical energy conversion device of claim 1, wherein the energy conversion site provides a charge separating function, the charge separating function provided as an integral part of each of at least a subset of the antennas within the array.

12. The light-to-electrical energy conversion device of claim 1, wherein the energy conversion site provides a charge separating function in the form of one of a pn or Schottky barrier junction, the charge separating function provided as an integral part of each of at least a subset of the antennas within the array.

13. The light-to-electrical energy conversion device of claim 12, wherein a variation in a dopant and establishing dimensions establishes wavelength response of the antennas.

14. The light-to-electrical energy conversion device of claim 12, wherein a variation in a dimensional characteristic of an optical conversion material, and dimensions of the antennas establish wavelength response of the antennas.

15. The light-to-electrical energy conversion device of claim 1, wherein the energy conversion site provides a light to electricity converting functions provided as an integral part of each of at least a subset of the antennas within the array.

16. The light-to-electrical energy conversion device of claim 1, comprising provided as rectenna structures, wherein the rectenna structures provide rectifier and antenna functions.

17. A nanostructural array of optical detection sites (“optical antennas”) formed of light wave detecting cavities immediately adjacent to quantum-confined electron spaces (with the latter constituting the “absorbing mass”), comprised of a plurality of individual light detection site, each of said optical detection sites containing a charge rectifying structure (such as a pn junction), thus forming a “rectenna” of sub-micron dimensions.

18. The nanostructural array of claim 17, wherein an area of each optical detection site includes antenna site includes the light wave detecting cavity forming the largest part of said area, and the light wave detecting cavity fabricated to exhibit a dimension of lambda/2n, where n is the index of refraction of the absorbing medium.

19. The nanostructural array of claim 18, wherein the light detecting cavity achieves a reception of a light wavelength detected as a function of the dimensionality of the cavity.

20. The nanostructural array of claim 17, further comprising the array provided as a surface nanostructure, such that lateral modifications of the surface nanostructure result in control of optical response.

21. A nanostructure of a light-to-electrical energy conversion device comprising an etched or otherwise formed tunable cavity capable of absorbing light, said cavity immediately adjacent to a region of fixed dimension of the substrate corresponding to electrical quantum confinement (EQC), wherein the cavity and the region of EQC taken together forming an individual antenna site.

22. The nanostructure of claim 21, further comprising the light-to-electrical energy conversion device absorbing the light as a classical physics waveform.

23. The nanostructure of claim 21, comprising light wavelengths of absorption determined by dimensionality of the cavities of the surface nanostructure, wherein a lateral dimension of the cavities present a dimension corresponding to a quantum characteristic of the light under conversion in accordance with a wavelength of the light and a refractive index of the absorbing medium.

24. The nanostructure of claim 21, comprising light wavelengths of absorption determined by dimensionality of the cavities of the surface nanostructure, wherein a lateral dimension of the cavities present a dimension corresponding to a quantum characteristic of the light under conversion in accordance with a wavelength of the light and a refractive index of the absorbing medium, each cavity having a depth in the range of 5-50 microns.

25. The nanostructure of claim 21, comprising light wavelengths of absorption determined by dimensionality of the cavities of the surface nanostructure, wherein a lateral dimension of the cavities present a dimension lambda/2n where lambda is the wavelength of light and n is the refractive index of the absorbing medium, each cavity having a depth in the range of 5-50 microns.

26. The nanostructure of claim 21, wherein each mm² of area of the conversion device comprises approximately 1500 individual antenna or light-to-electrical energy conversion sites.

27. The nanostructure e of claim 21, comprising a wavelength broadening “Q” of each antenna site will geometrically determined by a degree of taper of the EQC structure.

28. The nanostructure of claim 21, comprising the cavities and EQC centers configured to provide an intended optical response characteristic.

29. The nanostructure of claim 28, comprising the cavities and EQC centers configured with at least one EQC center surrounded by a ring of wavelength tuned cavities for detection of a polarization characteristic of the absorbed light.

30. A method for forming light-to-electrical energy conversion device comprising a nanostructure formed on the surface of a silicon or other semiconductor substrate that forms an array of antennas resonant at optical wavelengths, each of the antennas including an energy conversion site, the method comprising:
providing a starting substrate;
establishing a pattern for etching on the substrate corresponding to dimensions of the antennas;
applying a wet etch to the substrate while applying an electrical field to the wafer; and
controlling the wet etch so that the nanostructure exhibits light wavelengths of absorption determined by dimensionality of the cavities of the surface nanostructure, wherein a lateral dimension of the cavities present a dimension in accordance with a wavelength of the light and a refractive index of the absorbing medium.

31. The method of claim 30, comprising using a variation in an optical conversion material and adjusting dimensions to control wavelength response of the antennas.

32. The method of claim 30, comprising using a variation in a dopant and adjusting dimensions to control wavelength response of the antennas.

33. The method of claim 30, comprising providing an illumination of the surface of the substrate during the etch process, using an illumination source having a spectral characteristic corresponding to at least one dimensional characteristic of the antenna structures.

34. The method of claim 30, comprising providing an illumination of the surface of the substrate during the etch process, using an illumination source having a spectral characteristic corresponding to at least one dimensional characteristic of the antenna structures, wherein an illumination at a selected wavelength produces a corresponding frequency response of the antennas.

35. The method of claim 30, comprising providing an illumination of the surface of the substrate during the etch process, using an illumination source having at least two spectral components at wavelengths selected to produce a corresponding frequency response of the antennas.

36. The method of claim 30, comprising providing an illumination of the surface of the substrate during the etch process, using an illumination source having a spectral characteristic corresponding to a plurality of discrete wavelengths, to thereby provide a plurality of multiple discrete wavelength responses so as to provide a spectral response of the substrate in a predetermined set of primary colors.

37. The method of claim 30, comprising providing a raster scan of the surface of the substrate prior to the etch process, to thereby provide a corresponding pattern of etching of the substrate.

38. The method of claim 30, comprising selecting the lateral dimension of the cavities present at a dimension lambda/2n where lambda is the wavelength of light and n is the refractive index of the absorbing medium.

39. An optical transducer providing enhanced optical conversion characteristics, the transducer comprising:
an inner transducer plane;
a plurality of spaced structures spaced so as to form antennae for transducing at least one wavelength λ of light;
the spaced structures having separation dimensions between antennae of less than the wavelength λ of the light transduced, thereby enhancing the transfer of light at the transduced wavelengths; and
an electrical transducer structure associated with the antennae to convert energy between electrical energy and optical energy.

40. The optical transducer of claim 39, wherein the optical transducer structure includes a semiconductor junction providing a separation of charge carriers and generating electrical current.

41. The optical transducer of claim 39, wherein:
the optical transducer structure includes a semiconductor junction providing a separation of charge carriers and generating electrical current; and
the plurality of spaced structures forms an array having dimensions permitting each of a plurality of cells defined by the plurality of spaced structures to detect a single photon without the chance of the impingement or phase cancellation of a second photon.

42. The optical transducer of claim 39, comprising:
the electrical transducer structure including a semiconductor junction such that includes providing a separation of charge carriers and generating electrical current, the semiconductor junction established by a change in minority carrier concentration extending laterally across the plurality of spaced structures, thereby providing an upper junction region of minority carriers of a first sense and a lower junction region of minority carriers of a second sense; and
a top conductive structure connecting to the upper junction region.

43. The optical transducer of claim 39, comprising:
the electrical transducer structure including a semiconductor junction such that includes providing a separation of charge carriers and generating electrical current, the semiconductor junction established by a change in minority carrier concentration extending laterally across the plurality of spaced structures, thereby providing an upper junction region of minority carriers of a first sense and a lower junction region of minority carriers of a second sense; and
a top plate forming conductive structure connecting to the upper junction region.

44. The optical transducer of claim 43, wherein the top plate comprises indium tin oxide (ITO).

45. The optical transducer of claim 39, wherein a variation in a dimensional characteristic of an optical conversion material, and dimensions of the antennas establish wavelength response of the antennas.

46. The optical transducer of claim 39, wherein the energy conversion site provides a light to electricity converting functions provided as an integral part of each of at least a subset of the antennas within the array.

47. The optical transducer of claim 39, wherein a spacing of the plurality of spaced structures defines a frequency response of the optical transducer.

48. The optical transducer of claim 39, wherein:
the plurality of spaced structures exhibits a regular spacing; and
the spacing defines a frequency response of the optical transducer.

49. The optical transducer of claim 39, wherein:
the plurality of spaced structures have a spacing within a predetermined range; and
the predetermined range defines a frequency response range of the optical transducer.

50. The optical transducer of claim 39, wherein:
the plurality of spaced structures have a spacing within a predetermined range;
the plurality of spaced structures exhibits a regular spacing; and
the spacing defines a frequency response of the optical transducer.

51. The optical transducer of claim 39, wherein the plurality of spaced structures enhance transfer of light of the at least one transduced wavelength by transducing light quantum energy laterally in the transducer plane between subwavelength-spaced optical antennae structures comprising quantum optimized electron sites.

52. The optical transducer of claim 39, wherein the separation dimensions between antennae corresponds to a dimension determined by the wavelength of light transduced.

53. The optical transducer of claim 39, wherein:
the separation dimensions between antennae corresponds to a dimension determined by the wavelength of light transduced and an index of refraction of at least a portion of the antennae;
the material occupying the space between antennae is selected from air, an inert gas, a charged gas, a liquid, a transparent solid, a semi-transparent solid, and combinations thereof.

54. The optical transducer of claim 39, wherein the separation dimensions between antennae ranges within a range determined by a spectral characteristic corresponding to a wavelength characteristic of light transduced by the antennae, for transducing a corresponding spectrum of incident light.

55. The optical transducer of claim 39, wherein the plurality of spaced structures have thickness dimensions less than wavelengths of light transduced.

56. The optical transducer of claim 39, further comprising at least a portion of the plurality of spaced structures formed as elongate structures extending from the inner transducer plane

57. The optical transducer of claim 39, wherein the plurality of spaced structures extend substantially normal to the inner transducer plane

58. The optical transducer of claim 39, wherein the plurality of spaced structures enhance transfer of light of the at least one transduced wavelength by transducing light quantum energy laterally in the transducer plane between subwavelength-spaced optical antennae structures comprising quantum optimized electron sites.

59. The optical transducer of claim 39, wherein the plurality of elongate structures enhance transfer of light at the transduced wavelengths as optical antenna structures by forming spatial quantum confined electron sites.

60. The optical transducer of claim 39, further comprising at least a portion of the plurality of spaced structures formed as pores structures extending from a top surface to the inner transducer plane.

61. The optical transducer of claim 60, wherein the plurality of spaced structures extend substantially normal to the inner transducer plane.

62. The optical transducer of claim 39, wherein the plurality of spaced structures enhance transfer of light of the at least one transduced wavelength by transducing light quantum energy laterally in the transducer plane between subwavelength-spaced optical antennae structures comprising quantum optimized electron sites.

63. The optical transducer of claim 39, wherein the plurality of elongate structures enhance transfer of light at the transduced wavelengths as optical antenna structures by forming spatial quantum confined electron sites.

64. The optical transducer of claim 39, further comprising at least a portion of the plurality of spaced structures formed as porous forms.

65. The optical transducer of claim 64, wherein the plurality of spaced structures are formed as porous forms in porous silicon.

66. The optical transducer of claim 64, further comprising at least a portion of the plurality of spaced structures formed as porous forms extending through a surface of a silicon plate.

67. The optical transducer of claim 64, wherein the plurality of spaced structures extend substantially normal to the inner transducer plane.

68. The optical transducer of claim 64, wherein the plurality of spaced structures enhance transfer of light of the at least one transduced wavelength by transducing light quantum energy laterally in the transducer plane between subwavelength-spaced optical antennae structures comprising quantum optimized electron sites.

69. The optical transducer of claim 64, wherein the plurality of spaced structures enhance transfer of light at the transduced wavelengths as optical antenna structures by forming spatial quantum confined electron sites.

70. The optical transducer of claim 39, wherein the optical transducer is present in a solar cell.

71. The optical transducer of claim 39, wherein a voltage applied to the inner transducer plane causes emission of photons having at least one wavelength of light from the plurality of spaced structures, wherein the at least one wavelength of light emitted has a wavelength of about twice the separation dimension between antennae.

72. The optical transducer of claim 39, wherein the optical transducer is present in a light emitting diode.
